(19) United States
(12) Patent Application Publication
(10) Pub. No.: US 2017/0069694 A1
(43) Pub. Date: Mar. 9, 2017

(54) ORGANIC EL DISPLAY PANEL AND METHOD FOR MANUFACTURING SAME

(71) Applicant: JOLED INC., Tokyo (JP)

(72) Inventors: Hiroyuki AJIKI, Tokyo (JP); Akinobu IWAMOTO, Tokyo (JP); Atsushi TSUNO, Tokyo (JP); Syouzou NINOMIYA, Osaka (JP)

(73) Assignee: JOLED INC., Tokyo (JP)

(21) Appl. No.: 15/123,463

(22) PCT Filed: Jul. 3, 2014
(86) PCT No.: PCT/JP2014/003544

§ 371 Date: Sep. 2, 2016

(30) Foreign Application Priority Data
Mar. 13, 2014 (JP) 2014-050209

(51) Int. Cl. H01L 27/32

(52) U.S. Cl. CPC H01L 27/3246; H01L 27/326; H01L 2227/323

(57) ABSTRACT

An organic EL display panel including: a pair of first banks, second banks, and functional layers. The first banks have a greater length in a first direction than in a second direction orthogonal to the first direction and have a gap therebetween. The second banks span the gap and are disposed at intervals along the first direction. The functional layers are disposed within respective ones of recesses defined by the first banks and the second banks and each correspond to at least a portion of an organic EL element. Each of the second banks has a groove at an upper surface thereof. The groove connects recesses adjacent to each other with the second bank therebetween and has a width, along the second direction, smaller than a width of the adjacent recesses along the second direction and within an inclusive range from 2 μm to 6 μm.

### TECHNICAL FIELD

The present invention relates to an organic electroluminescence (EL) display panel including an organic EL element and a manufacturing method of such an organic EL display panel.

### BACKGROUND ART

Recently, organic electroluminescence (EL) elements are researched and developed. An organic EL element includes a pair of electrodes consisting of an anode and a cathode, and a light-emitting layer disposed therebetween. The organic EL element further includes a hole injection layer, a hole transport layer, and/or a hole injection/transport layer between the anode and the light-emitting layer as necessary. Also, the organic EL element includes an electron injection layer, an electron transport layer, and/or an electron injection/transport layer between the cathode and the light-emitting layer as necessary. Each of such layers disposed between the electrodes achieves a specific function, such as emission of light, injection of charge carriers, or transport of charge carriers. Due to this, such layers are referred to as functional layers.

An organic EL display panel may employ such organic EL elements as subpixels of the colors red, green, and blue. A set of adjacent subpixels respectively corresponding to the colors red, green, and blue constitute a pixel.

The so-called “wet process” is being proposed as a process for manufacturing an organic EL display panel. The wet process involves applying a solution including a functional material for forming a functional layer to regions on the substrate where the subpixels are to be formed, and drying the applied solution. Typically, in the wet process, banks for keeping the solution at desired positions are formed first, and then the solution is applied to recesses defined by the banks.

Patent Literature 1 discloses banks of a so-called pixel bank structure (for example, see FIG. 12 of Patent Literature 1). A pixel bank structure is composed of a plurality of elongated first banks that are parallel with each other, and a plurality of second banks disposed between adjacent ones of the first banks. In the pixel bank structure, each combination of two adjacent first banks and two adjacent second banks defines one recess, and each of such recesses corresponds to one region within which one subpixel is to be formed.

### CITATION LIST

### Patent Literature

[Patent Literature 1]

WO 2009/084209 A1

### SUMMARY OF INVENTION

### Technical Problem

When employing the wet process, the amount of the solution applied may unfortunately vary among the recesses. In such a case, functional layers formed in the recesses by drying the solution may have different thicknesses. This results in the subpixels having different light-emitting property.

One aspect of the present invention is a technology that suppresses a difference in functional layer thickness among the subpixels.

### Solution to Problem

An organic electroluminescence (EL) display panel pertaining to one aspect of the present invention includes: a pair of first banks, each of the first banks having a greater length in a first direction than in a second direction orthogonal to the first direction, the pair of first banks disposed with a gap therebetween along the second direction; a plurality of second banks each spanning the gap between the first banks, the second banks disposed at intervals along the first direction; and a plurality of functional layers disposed within respective ones of a plurality of recesses defined by the first banks and the second banks, each of the functional layers corresponding to at least a portion of an organic EL element. In the organic EL display panel, each of the second banks has a groove at an upper surface thereof, the groove connecting adjacent recesses, and having a width, along the second direction, smaller than a width of the adjacent recesses along the second direction and within an inclusive range from 2 μm to 6 μm, the adjacent recesses being ones of the plurality of recesses that are adjacent to each other with the second bank therebetween.

### Advantageous Effects of Invention

The above configuration suppresses a difference in functional layer thickness among the recesses.

### BRIEF DESCRIPTION OF DRAWINGS

FIG. 1 is a partial cross-sectional view illustrating an organic EL display panel pertaining to an embodiment of the present invention.

FIG. 2 is a perspective view illustrating a bank structure.

FIG. 3A is a plan view illustrating the bank structure, FIG. 3B is a cross-sectional view illustrating the bank structure taken along line A-A, FIG. 3C is a cross-sectional view illustrating the bank structure taken along line B-B, and FIG. 3D is a magnified plan view illustrating the bank structure.

FIGS. 4A and 4B illustrate how a width of a groove is measured.

FIG. 5A is a plan view illustrating the bank structure with an applied solution, and FIG. 5B is a cross-sectional view illustrating the bank structure with the applied solution.

FIGS. 6A, 6B, and 6C illustrate how a drying process of the solution progresses.

FIGS. 7A and 7B show traced photographs of organic EL display panels obtained through an experiment. FIG. 7A illustrates a sample for a groove having a width of 10 μm, and FIG. 7B illustrates a sample for a groove having a width of 4 μm.

FIGS. 8A, 8B, 8C, and 8D illustrate results of an experiment for examining a degree of uniformity of a thickness of a functional layer.

FIGS. 9A and 9B illustrate results of an experiment for examining how a defective subpixel affects surrounding subpixels.

FIGS. 10A, 10B, 10C, 10D, and 10E are partial cross-sectional views illustrating processes for manufacturing the organic EL display panel pertaining to the embodiment of the present invention.

FIGS. 11A, 11B, and 11C are partial cross-sectional views illustrating processes for manufacturing the organic EL display panel pertaining to the embodiment of the present invention.

FIGS. 12A and 12B are magnified plan views illustrating modified groove shapes. FIG. 12A illustrates a first modified groove shape, and FIG. 12B illustrates a second modified groove shape.

FIG. 13 is an external view illustrating a display device.

FIG. 14 is a functional block diagram of the display device.

### DESCRIPTION OF EMBODIMENTS

### <1> Overview of Aspects of Present Invention

An organic electroluminescence (EL) display panel includes: a pair of first banks, each of the first banks having a greater length in a first direction than in a second direction orthogonal to the first direction, the pair of first banks disposed with a gap therebetween along the second direction; a plurality of second banks each spanning the gap between the first banks, the second banks disposed at intervals along the first direction; and a plurality of functional layers disposed within respective ones of a plurality of recesses defined by the first banks and the second banks, each of the functional layers corresponding to at least a portion of an organic EL element. In the organic EL display panel, each of the second banks has a groove at an upper surface thereof, the groove connecting adjacent recesses, and having a width, along the second direction, smaller than a width of the adjacent recesses along the second direction and within an inclusive range from 2 μm to 6 μm, the adjacent recesses being ones of the plurality of recesses that are adjacent to each other with the second bank therebetween.

Also, in the organic EL display panel, for each of the second banks, the width of the groove along the second direction may be equal to or smaller than one fourth of the width of the adjacent recesses along the second direction.

Also, in the organic EL display panel, upper surfaces of the first banks may be flush with upper surfaces of the second banks, and for each of the second banks, the groove may have a depth equal to or greater than 30% of a height of the first banks.

Also, in the organic EL display panel, the second banks may include an electrically insulating material, and for each of the second banks, the depth of the groove may be equal to or less than a value calculated by subtracting 300 nm from the height of the first banks.

Also, in the organic EL display panel, each of the second banks may separate one of the functional layers in one of the adjacent recesses from another of the functional layers in the other of the adjacent recesses.

Also, in the organic EL display panel, the functional layers may include an organic material.

Also, in the organic EL display panel, the groove may have different widths along the second direction at different positions thereof along the first direction, and the width within the inclusive range from 2 μm to 6 μm may be a width at a position where the groove has a minimum width along the second direction.

Also, in the organic EL display panel, the groove may include: two end portions each connecting with one of the adjacent recesses; and a central portion between the two end portions,, and the width of the groove along the second direction may gradually decrease from the two end portions of the groove to the central portion of the groove.

A manufacturing method of an organic EL display panel includes: forming a pair of first banks, each of the first banks having a greater length in a first direction than in a second direction orthogonal to the first direction, the pair of first banks disposed with a gap therebetween along the second direction; forming a plurality of second banks each spanning the gap between the first banks and disposed at intervals along the first direction; and forming a plurality of functional layers disposed within respective ones of a plurality of recesses defined by the first banks and the second banks, each of the functional layers corresponding to at least a portion of an organic EL element. In the manufacturing method, each of the second banks has a groove at an upper surface thereof, the groove connecting adjacent recesses, and having a width, along the second direction, smaller than a width of the adjacent recesses along the second direction and within an inclusive range from 2 μm to 6 μm, the adjacent recesses being ones of the plurality of recesses that are adjacent to each other with the second bank therebetween, and the functional layers are formed by applying a solution including a functional material and drying the applied solution, the applied solution including portions positioned in the recesses and portions positioned in the grooves of the second banks.

### <2> Structure of Organic EL Display Panel

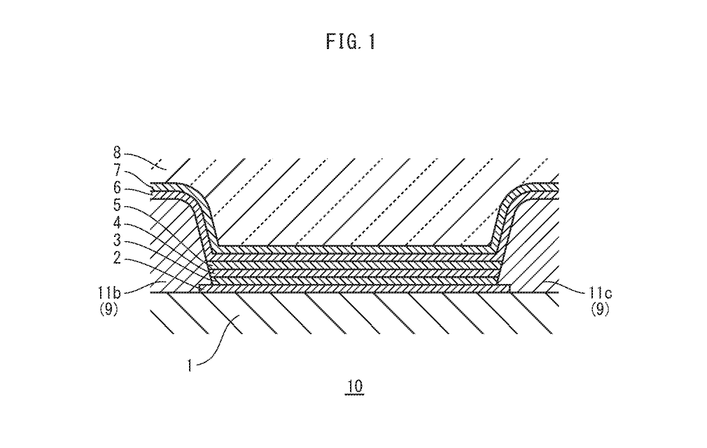

FIG. 1 is a partial cross-sectional view illustrating an organic EL display panel pertaining to an embodiment of the present invention. FIG. 1 illustrates one subpixel. An organic EL display panel 10 includes a substrate 1, an anode 2, a hole injection layer 3, a hole transport layer 4, an organic light-emitting layer 5, an electron transport layer 6, a cathode 7, a sealing layer 8, and a bank structure 9. When a voltage is applied between the anode 2 and the cathode 7, holes are supplied from the anode 2 to the organic light-emitting layer 5 via the hole injection layer 3 and the hole transport layer 4. Also, electrons are supplied from the cathode 7 to the organic light-emitting layer 5 via the electron transport layer 6. The holes and the electrons recombine with each other in the organic light-emitting layer 5, and this recombination causes the organic light-emitting layer 5 to emit light. The stack of layers from the anode 2 to the cathode 7 forms one organic EL element. The sealing layer 8 prevents intrusion of moisture and oxygen in the atmosphere into the organic EL element. In the present embodiment, the hole injection layer 3, the hole transport layer 4, and the organic light-emitting layer 5 are formed by the wet process. The bank structure 9 separates each of the hole injection layer 3, the hole transport layer 4, and the organic light-emitting layer S of the subpixel from the corresponding layer in an adjacent subpixel. Meanwhile, each of the electron transport layer 6 and the cathode 7 extends from the subpixel to adjacent subpixels over the bank structure 9. Specific materials for each of the layers are described later.

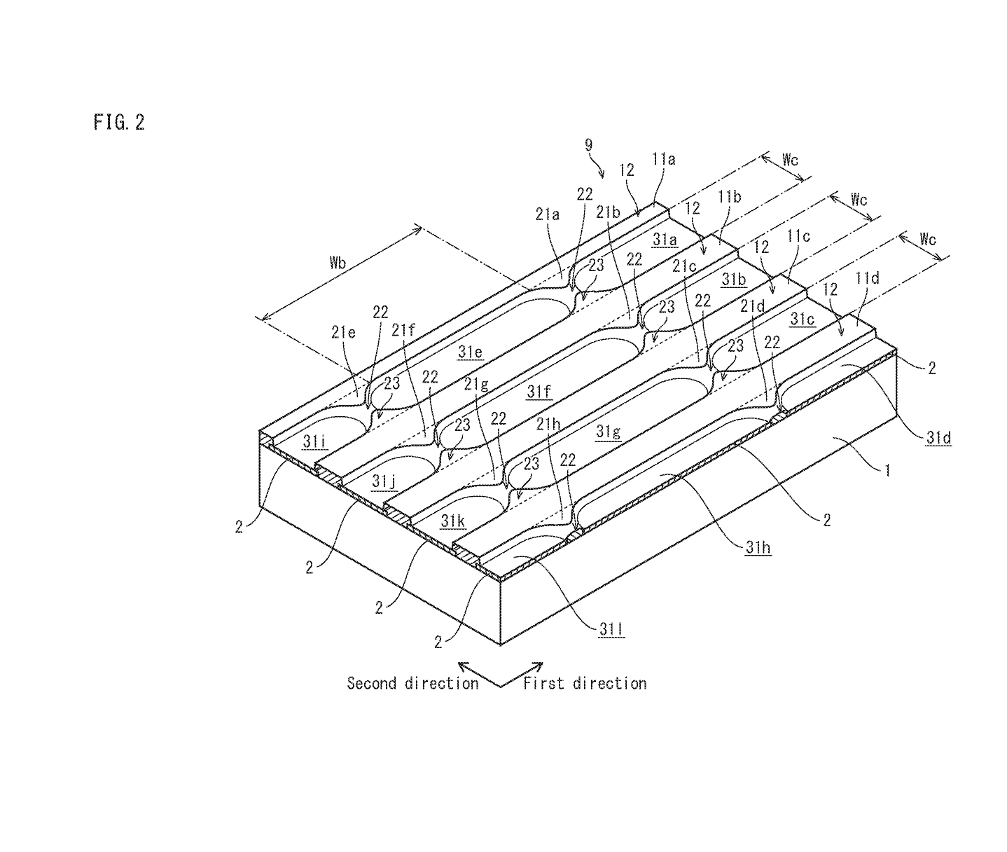

The bank structure 9 has, as illustrated in a perspective view in FIG. 2, a grid pattern on the whole. In FIG. 2, in order to illustrate the shape of the bank structure 9 clearly, the hole injection layer 3 and the layers above the hole injection layer 3 are omitted. The bank structure 9 includes first banks 11a, 11b, 11c, and 11d (hereinafter, wherever it is unnecessary to distinguish the first banks 11a, 11b, 11c, and 11d from one another, the first banks 11a, 11b, 11c, and 11d are simply referred to as the first banks 11) and second banks 21a, 21b, 21c, 21d, 21e, 21f, 21g, and 21h (hereinafter, wherever it is unnecessary to distinguish the second banks 21a, 21b, 21c, 21d, 21e, 21f, 21g, and 21h from one another, the second banks 21a, 21b, 21c, 21d, 21e, 21f, 21g, and 21h are simply referred to as the second banks 21).

The first banks 11 have an elongated shape, and are parallelly disposed on the substrate 1 spaced away from one another by a gap of a width Wc. In the present embodiment, in any plane parallel to an upper surface of the substrate 1, a direction parallel to the first banks 11 is referred to as a “first direction”, and a direction orthogonal to the first direction is referred to as a “second direction”. Each of the second banks 21 is disposed between an adjacent pair of the first banks 11. Each of the second banks 21 is spaced away from an adjacent second bank 21 by an interval of a width Wb. Each of the second banks 21 connects two adjacent first banks 11. The first banks 11 and the second banks 21 define recesses 31a, 31b, 31c, 31d, 31e, 31f, 31g, 31h, 31i, 31j, 31k, and 31l (hereinafter, wherever it is unnecessary to distinguish the recesses 31a, 31b, 31c, 31d, 31e, 31f, 31g, 31h, 31i, 31j, 31k, and 31l from one another, the recesses 31a, 31b, 31c, 31d, 31e, 31f, 31g, 31h, 31i, 31j, 31k, and 31l are simply referred to as the recesses 31). For example, the recess 31f is defined by the first banks 11b and 11c and the second banks 21b and 21f. Each of the recesses 31 is a region within which a subpixel is to be formed. That is, above each of the recesses 31, the hole injection layer 3, the hole transport layer 4, the organic light-emitting layer 5, the electron transport layer 6, and the cathode 7 are formed.

The first banks 11 have the same height as each other, and the second banks 21 have the same height as each other. In the present embodiment, the height of the first banks 11 and the height of the second banks 21 are also the same as each other. Therefore, upper surfaces 12 of the first banks 11 are flush with upper surfaces 23 of the second banks 21. Each of the second banks 21 has a groove 22 at the upper surface 23. Each of the grooves 22 connects two adjacent recesses 31 with a second bank 21 therebetween in the first direction. For example, the groove 22 of the second bank 21b connects the recesses 31b and 31f, which are adjacent to each other with the second bank 21b therebetween. Also, the groove 22 of the second bank 21f connects the recesses 31f and 31j, which are adjacent to each other with the second bank 21f therebetween. That is, the recesses 31 disposed between two adjacent first banks 11 are connected to each other by the grooves 22 of the second banks 21 between the two adjacent first banks 11.

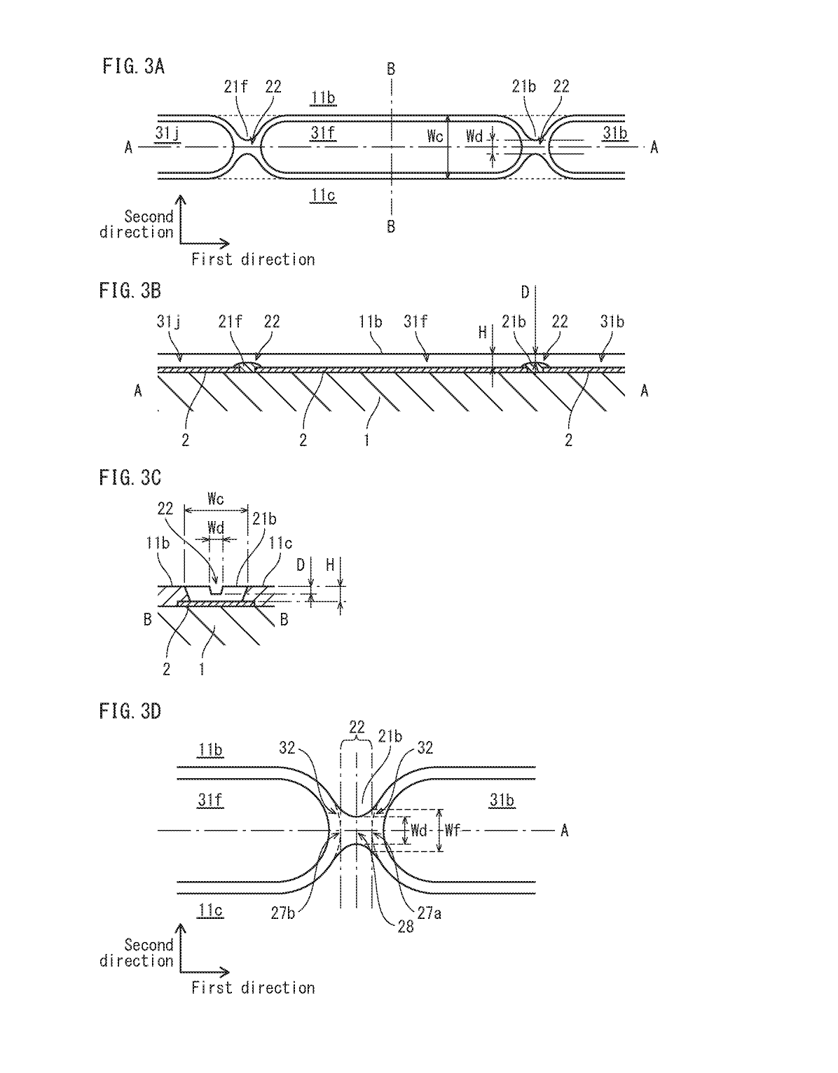

FIG. 3A is a plan view illustrating the bank structure, FIG. 3B is a cross-sectional view illustrating the bank structure taken along line A-A, FIG. 3C is a cross-sectional view illustrating the bank structure taken along line B-B, and FIG. 3D is a magnified plan view illustrating a second bank. As illustrated in FIG. 3A, each groove 22 extends along the first direction. The groove 22 has a width Wd in the second direction, which is smaller than a width We of each recess 31 in the second direction. The width We is, for example, within an inclusive range from 30 μm to 40 μm. The width Wd is, for example, within an inclusive range from 2 μm to 6 μm. The width Wd may be equal to or smaller than one fourth of the width Wc.

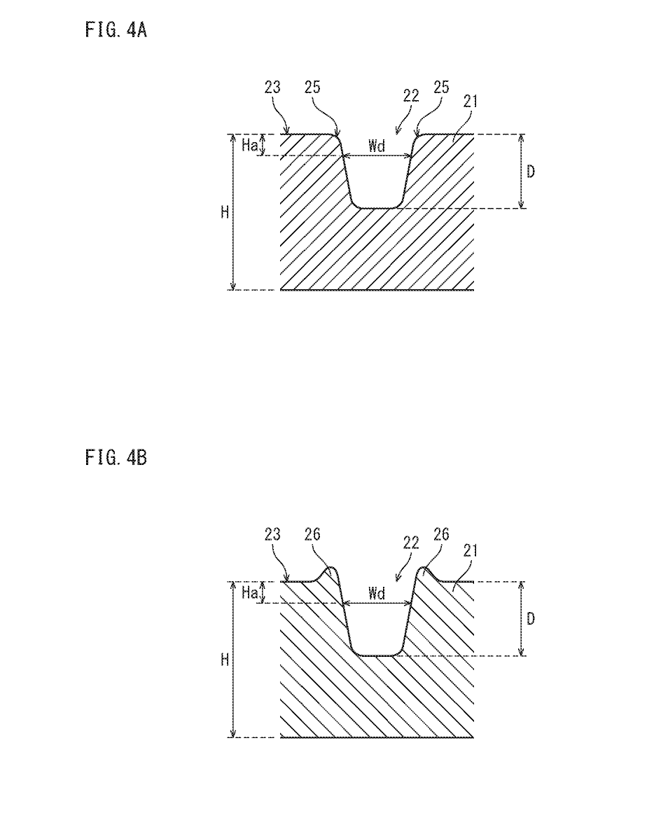

In reality, as illustrated in a cross-sectional view in FIG. 4A, there are some cases where a connecting point 25 that connects the upper surface 23 of a second bank 21 and an inner surface of a groove 22 may have a round shape. Also, as illustrated in a cross-sectional view in FIG. 4B, a connecting point 26 that connects the upper surface 23 of a second bank 21 and an inner surface of a groove 22 may have a protrusion. Further, as illustrated in FIGS. 4A and 4B, the width of the groove 22 may differ at different positions of the groove 22 along a depth direction. In view of the above cases, in the present disclosure, the width Wd is measured at a position lower than the upper surfaces 23 of the second banks 21 by Ha. Ha corresponds to 5% of a height of the second banks 21. The height of the second banks 21 is a height from bottom surfaces of the recesses 31 to the upper surfaces 23 of the second banks 21. In the present embodiment, the bottom surface of a recess 31 corresponds to an upper surface of an anode 2. The height of the upper surfaces 23 of the second banks 21 is measured at flat portions of the upper surfaces 23. Here, the first banks 11 and the second banks 21 are considered to have the same height H, which is, for example, within an inclusive range from 1 μm to 2 μm.

As illustrated below, providing the grooves 22 of the second banks 21 with a width Wd in the second direction within the inclusive range from 2 μm to 6 μm suppresses a difference in the thickness of a functional layer formed by the wet process (any one of the hole injection layer 3, the hole transport layer 4, and the organic light-emitting layer 5 in the present embodiment) among the recesses 31.

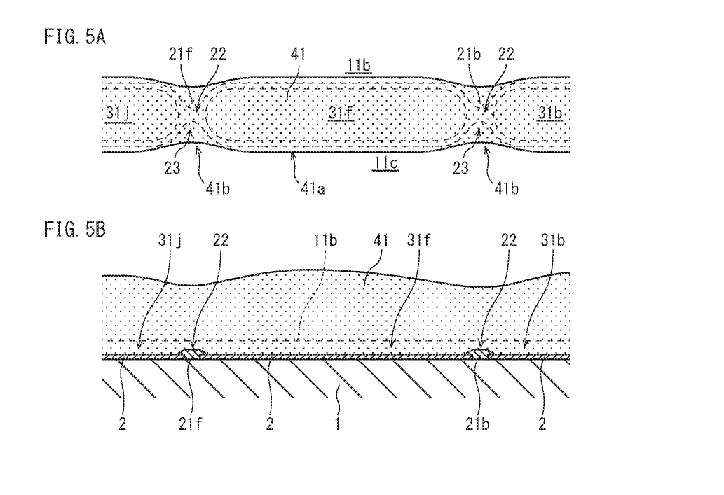

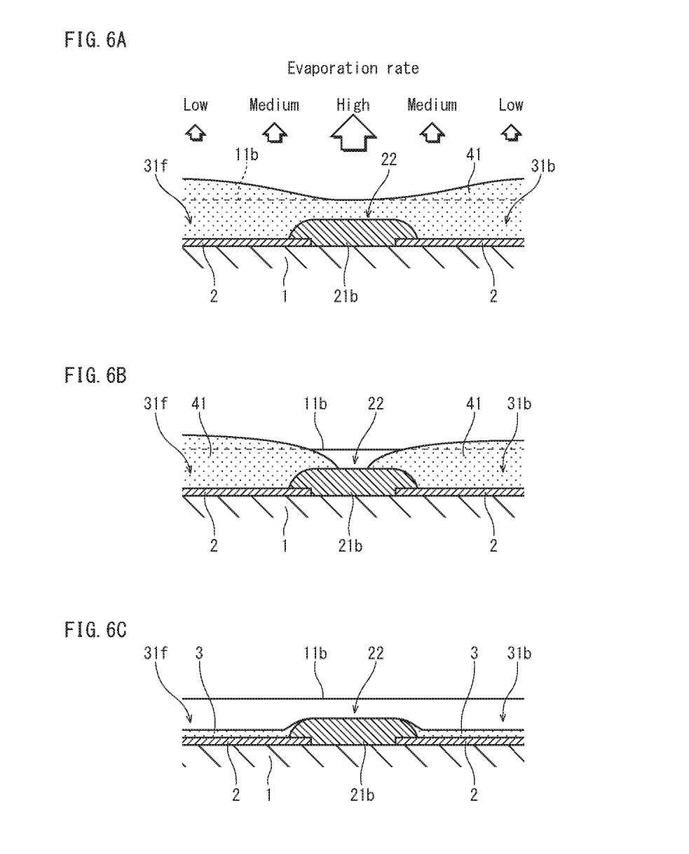

FIGS. 5A, 5B, 6A, 6B, and 6C illustrate processes of forming a functional layer.

As illustrated in FIGS. 5A and 5B, a solution 41 is applied to the recesses 31. The solution 41 includes a solvent and a functional material for forming the functional layer. The upper surfaces of the first banks 11 have liquid repellency. This prevents the solution 41 from flowing over the first bank 11 from one recess 31 into adjacent recesses 31 (not illustrated). Inner surfaces of the grooves 22 of the second banks 21 have lower liquid repellency than upper surfaces of the first banks 11. Because of this, as illustrated in FIGS. 5A and 5B, the solution 41 applied to one recess 31 connects with the solution 41 applied to an adjacent recess 31 via the grooves 22. Even when the amount of the solution in the recesses 31 differs at the point of application, the solution 41 applied to one recess 31 connects with the solution 41 applied to another recess 31, whereby the amount of the solution in the different recesses 31 is equalized. The upper surfaces 23 of the second banks 21 have a similar level of liquid repellency as the upper surfaces of the first banks 11. Accordingly, portions 41b of the solution 41 that cover the second banks 21 have a smaller width of than portions 41a of the solution 41 positioned in the recesses 31.

Drying of the solution progresses in the order of FIG. 6A, FIG. 6B, and FIG. 6C. In a time point illustrated in FIG. 6A, a portion of the solution 41 positioned in the recess 31b and a portion of the solution 41 positioned in the recess 31f are connected by a portion of the solution 41 over the second bank 21b. It is commonly known that an evaporation rate of a solution is inversely proportional to a power of the width of the solution. That is, the smaller the width of a solution is, the higher the evaporation rate of the solution is. As described above, the solution 41 applied to the recesses 31 and the grooves 22 has different widths at different positions in the first direction. Such portions of the solution 41 evaporate at different rates.

Specifically, after the drying of the solution 41 progresses to some extent, the solution 41 is accommodated inside the recesses 31 and the grooves 22, and the solution 41 is composed of portions having a width equal to the width of the recess 31 and portions having a width equal to the width of the grooves 22. At this point, the evaporation rate of the portions of the solution 41 positioned in the recesses 31 is determined by the width We of the recesses 31 and the evaporation rate of the portions of the solution 41 positioned in the grooves 22 is determined by the width Wd of the grooves 22. The portions of the solution 41 at the grooves 22 evaporate at a higher rate than at the portions of the solution 41 at the recesses 31. That is, the portions of the solution 41 within the groove 22 decrease rapidly.

FIG. 6B illustrates a time point at which portions of the solution 41 in the grooves 22 have decreased rapidly and the solution 41 is no longer existent within the grooves 22. FIG. 6B illustrates a portion of the solution 41 within the recess 31b and a portion of the solution 41 within the recess 31f, which are separate from each other.

FIG. 6C illustrates a time point at which the drying of the solution 41 has progressed further and the functional layer (in this example, the hole injection layer 3) has been formed. FIG. 6C illustrates the functional layer within the recess 31b and the functional layer within the recess 31f, which are separated from each other by the second bank 21b.

When the width Wd is large, the decrease of the portions of the solution 41 in the grooves 22 is moderate, and the solution 41 remains in the grooves 22 until the drying process of the solution 41 is close to an end. In such a case, a thin functional layer material portion may be formed within the grooves 22. On the other hand, when the width Wd is small, the decrease of the portions of the solution 41 in the grooves 22 is rapid, and the situation illustrated in FIG. 6B can be achieved with a high possibility during the drying process of the solution 41.

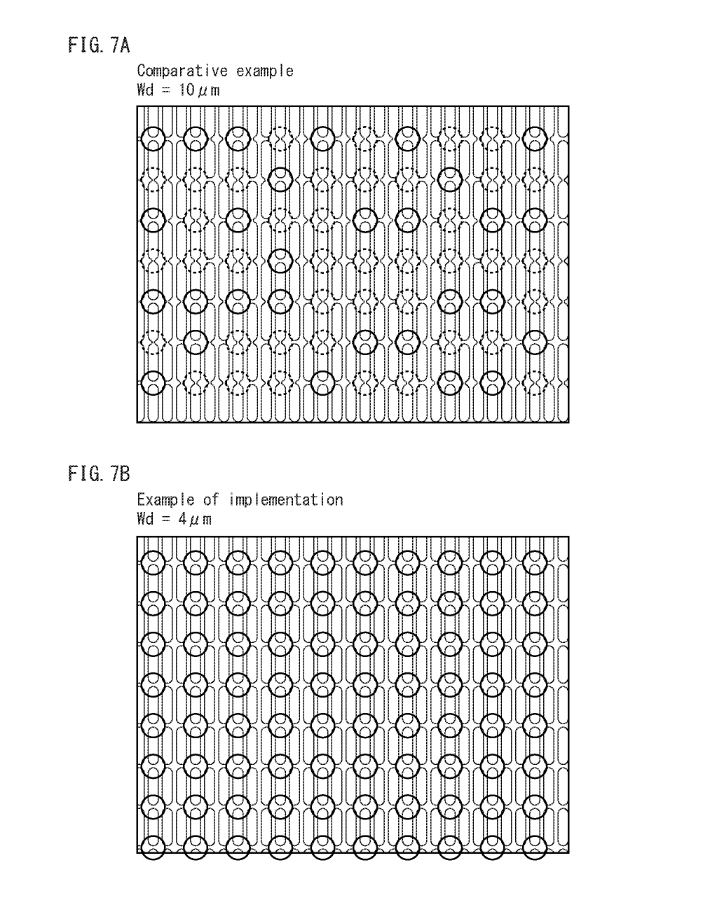

The inventors manufactured one organic EL display panel for each of different widths Wd of the grooves 22, and observed the functional layer formed in the organic EL display panel. The different widths Wd were 10 μm, 6 μm, 4 μm, 3 μm, and 2 μm. In all of the organic EL display panels, the recesses 31 had the same width We of 35 μm. FIGS. 7A and 7B show traced photographs of the samples. FIG. 7A illustrates a sample for the width Wd of 10 μm, and FIG. 7B illustrates a sample for the width Wd of 4 μm.

The sample for the width Wd of 10 μm included regions (indicated by circles in solid line) where two adjacent functional layers were separate from each other and regions (indicated by circles in broken line) where two adjacent functional layers were connected to each other. In a region where two adjacent functional layers were connected, a functional layer material portion was formed in the groove 22 between the two adjacent functional layers. Due to this, the two adjacent functional layers had a smaller thickness than desired. On the other hand, in the regions where two adjacent functional layers were separate, no functional layer material portion was formed in the groove 22 between the two adjacent functional layers. Due to this, the two adjacent functional layers had the desired thickness. As such, in the sample including regions where two adjacent functional layers were separate from each other and regions where two adjacent functional layers were connected to each other, the thickness of the functional layer unfortunately differed among subpixels.

In the sample for the width Wd of 4 μm, adjacent functional layers were separate at all regions (as indicated by circles in solid line). Accordingly, the difference in the thickness of the functional layer among the subpixels was suppressed. This experiment revealed that, a sample for the width Wd of 10 μm included regions where the two adjacent functional layers were separate from each other and regions where the two adjacent functional layers were connected to each other. In samples for the widths Wd of 6 μm, 4 μm, 3 μm, and 2 μm, respectively, two adjacent functional layers were separate at all regions. The above results indicate that providing the grooves 22 of the second banks 21 with a width Wd in the second direction within the inclusive range from 2 μm to 6 μm suppresses the difference in the thickness of the functional layer among the subpixels. In the sample for the width Wc of 35 μm and the width Wd of 10 μm (when the width Wd was greater than one fourth of the width Wc), as described above, both the regions where two adjacent functional layers were separate from each other and the regions where two adjacent functional layers were connected to each other were included. Providing the groove 22 with a width Wd equal to or smaller than one fourth of the width We suppresses the difference in the thickness of the functional layer among the subpixels.

In this experiment, the functional layer was formed by applying the ink-jet process, which is one example of the wet process. When applying the ink-jet process, it is desirable that viscosity of the solution be within an inclusive range from 5 mPa·s to 50 mPa·s, and that surface tension of the solution be within an inclusive range from 20 mN/m to 70 mN/m. Concentration of the functional material may be, for example, within an inclusive range from 0.01 wt % to 10.0 wt % of the entire solution. In this experiment, F8-F6 (copolymer composed of F8 (polydioctylfluorene) and F6 (polydihexylfluorene)) were utilized as the material for the functional layer. Viscosity and surface tension of a solution was measured by using, for example, AR-G2 rheometer manufactured by TA Instruments, Inc. The measurement was conducted under, for example, the temperature 20° C.

Returning to FIGS. 3B and 3C, the depth D is further considered. In order to prevent the solution 41 from flowing over a first bank 11 from one recess 31 into an adjacent recess 31, causing the bank structure 9 to exhibit liquid repellency around a surface portion thereof is sufficient. That is, the bank structure 9 does not necessarily exhibit liquid repellency at deeper portions thereof Applying liquid repellent treatment to the surface portion of the bank structure 9 is sufficient. In such a case, the bank structure 9 has a profile such that the liquid repellency decreases with distance from the surface portion. On the other hand, inner surfaces of the grooves 22 need to hold the solution. Accordingly, it is desirable that the inner surfaces of the grooves 22 have low liquid repellency. In cases where the bank structure 9 has the above profile, it is desirable to provide the grooves 22 with as great a depth D as possible. According to the inventors' discovery, the liquid repellency of the first banks 11 decreases to reach a sufficient level at positions lower than the upper surfaces of the first banks 11 by at least 30% of the height H. Accordingly, it is desirable that the depth D be equal to or greater than 30% of the height H.

The inventors further conducted an experiment for examining whether or not crosstalk occurs for different heights of the second banks. In this experiment, the second banks 21 were not provided with grooves. Crosstalk means a shift in a value of current of a certain subpixel from a desired value of current, caused by a magnetic field of an adjacent subpixel. The experiment revealed that crosstalk occurs when the height of the second banks is less than 300 nm, and crosstalk does not occur when the height of the second banks is equal to or greater than 300 nm. In the present embodiment, the upper surfaces 23 of the second banks 21 are flush with the upper surfaces 12 of the first banks 11. Accordingly, the upper surfaces 23 of the second banks 21 have a height equal to or greater than 300 nm. However, bottom surfaces of the grooves 22 can have a height lower than 300 nm depending on the depth D of the grooves 22, which may unfortunately cause crosstalk between adjacent subpixels. Therefore, it is desirable that the bottom surfaces of the grooves 22 of the second banks 21 have a height equal to or greater than 300 nm. That is, in order to suppress occurrence of crosstalk between adjacent subpixels, it is desirable that the depth D of the grooves 22 be smaller than the value obtained by subtracting 300 nm from the height H.

Further, as illustrated in FIG. 3D, end portions 27a and 27b of the groove 22 are intersections of a central axis A of one groove 22 along the first direction and outlines 32 of recesses 31 at both sides of the groove 22. A central portion 28 of the groove 22 is a center between the end portions 27a and 27b of the groove 22. As illustrated in FIG. 3D, the width of the groove 22 along the second direction differs at different positions of the groove 22 along the first direction. In the present disclosure, the width Wd of the groove 22 is measured at a position where the groove 22 has a minimum width along the second direction.

Further, as illustrated in FIG. 3D, the width of the groove 22 gradually decreases from the end portions 27a and 27b to the central portion 28, and is the smallest at the central portion 28. As described above, the evaporation rate of the solution is inversely proportional to a power of the width of the solution. Therefore, the evaporation rate of the solution is the highest at the central portion 28 of the groove 22. Because the evaporation rate of the solution is the highest only at one position (i.e. the central portion 28), in the drying process of the solution, the solution starts to separate only at the central portion 28 of the groove 22. However, when a groove 22 has a plurality of positions in which the evaporation rate is the highest, the position in the groove 22 at which the solution starts to separate can unfortunately be different from the position in another groove 22 at which the solution starts to separate. When the positions at which the solution starts to separate differs among the grooves 22, the amount of the solution unfortunately differs among the recesses 31. On the other hand, the present embodiment suppresses the difference in the amount of the solution among the recesses 31 because the starting point of separation of the solution is the same for all the grooves 22.

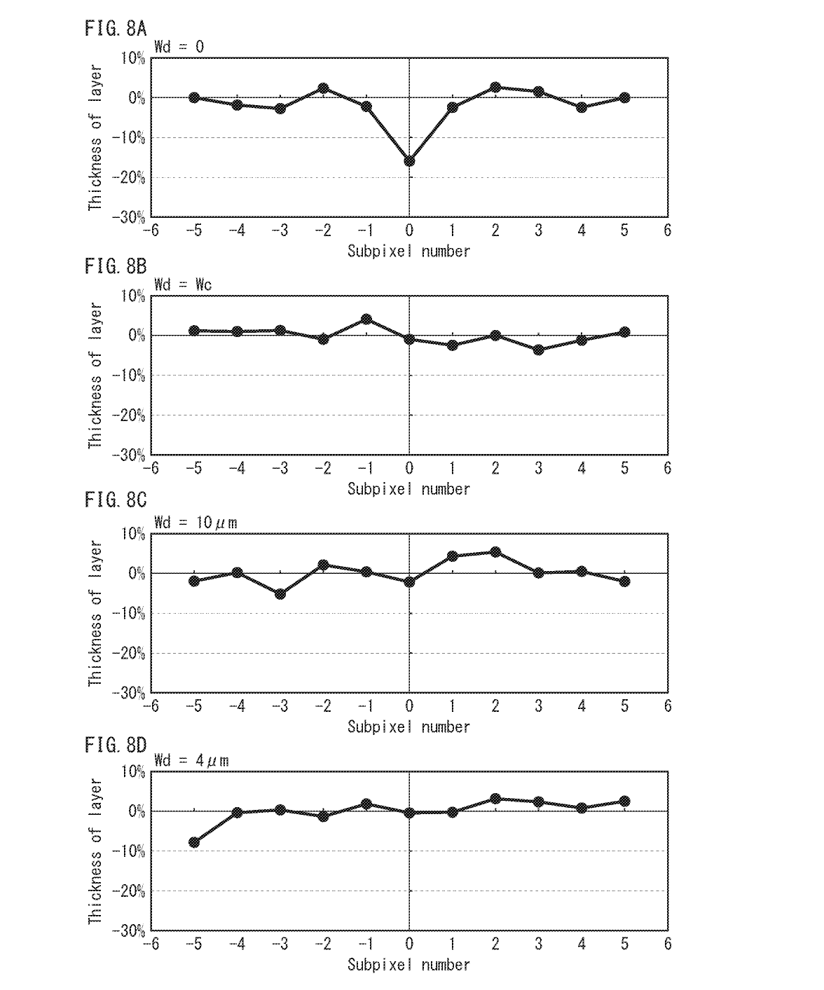

The inventors further conducted an experiment for proving that providing the groove 22 to each of the second banks 21 suppresses the difference in the thickness of the functional layer among the subpixels. FIGS. 8A, 8B, 8C, and 8D illustrate results of the experiment. FIG. 8A illustrates a case where the width Wd was set to zero, or that is, a case where the second banks did not have the grooves 22. This structure corresponds to a so-called pixel bank structure. A pixel bank structure refers to a structure in which the height of the first banks and the second banks are the same and the second banks do not have grooves. In a pixel bank structure, the solution applied to one recess is independent and does not connect with the solution applied to an adjacent recess. FIG. 8B illustrates a case where the width Wd was equal to the width Wc. This structure corresponds to a so-called line bank structure. A line bank structure refers to a structure in which the height of the second banks is lower than the height of the first banks, and the second banks do not have grooves. In a line bank structure, the solution applied to one recess connects with the solution applied to an adjacent recess by crossing over a second bank between the recesses. FIG. 8C illustrates a case where the width Wd was 10 μm. FIG. 8D illustrates a case where the width Wd was 4 μm. The horizontal axis of each of the graphs indicates sample numbers of subpixels (recesses). In this experiment, the solution was applied by the ink-jet process to recesses each assigned with one of the numbers from −5 to 5. The amount of the solution applied to the recess “0” was smaller than the amount of the solution applied to the other recesses. Then, a functional layer was formed within each of the recesses by drying the solution, and the thickness of the functional layer within each of the recesses was measured. According to the results of the measurements, in the case illustrated in FIG. 8A, the functional layer within recess “0” was thinner than the functional layers within the other recesses. This is because the solution positioned in one recess could not connect to the solution positioned in another recess in the pixel bank structure, and therefore equalizing of the amount of the solution in the recesses could not be achieved. On the other hand, in FIGS. 8B, 8C, and 8D, the thickness of the functional layer was equalized among the recesses. Further, in a case where the width Wd was 4 μm, equalizing the amount of the solution in the recesses was also achieved, to the same extent as in the case of the line bank structure.

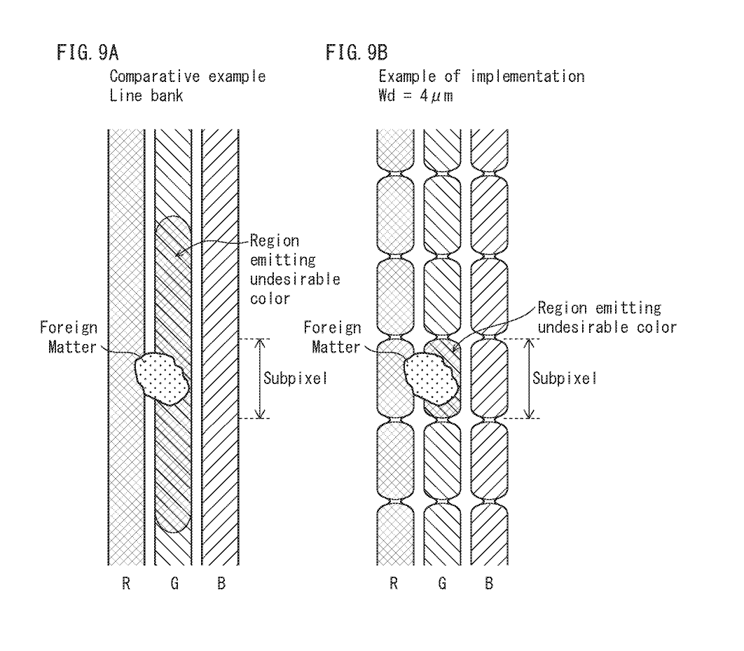

The inventors further conducted an experiment for examining how existence of a defective subpixel affects surrounding subpixels. FIGS. 9A and 9B schematically illustrate results of the experiment. FIG. 9A illustrates a case of a line bank structure. FIG. 9B illustrates the bank structure of the present embodiment, in which the width Wd is 4 μm. In this experiment, an organic light-emitting layer corresponding to one of the colors red (R), green (G), and blue (B) was formed within each of the subpixels. Then, how a region emitting an undesirable color expands around a subpixel containing a foreign matter was observed. The results indicate that, in the line bank structure, the subpixel containing the foreign matter emitted an undesirable color, and in addition, a plurality of subpixels around the subpixel containing the foreign matter also emitted an undesirable color. On the other hand, when the grooves 22 were disposed in the second banks 21, only the subpixel containing the foreign matter emitted an undesirable color, while subpixels adjacent to the subpixel containing the foreign matter emitted a desired color. Accordingly, the bank structure of the present embodiment can, even when a defective subpixel containing a foreign matter exists, suppress the spread of the defectiveness to surrounding subpixels.

### <3> Specific Materials for Layers

### (Substrate)

When the organic EL display panel 10 is of the active matrix type, the substrate 1 is a so-called thin film transistor (TFT) substrate. The TFT substrate includes a base material, a TFT layer formed on the base material, and an electrically insulating layer formed on the TFT layer. The TFT layer includes TFTs and wirings connected to the TFTs.

As a material for the base material, for example, glass or plastic can be utilized. Examples of such glass are alkali-free glass, soda glass, nonfluorescent glass, phosphate glass, borate glass, and quartz. Examples of such plastic are acrylic resin, styrenic resin, polycarbonate resin, epoxy resin, polyethylene, polyester, polyimide, and silicone resin.

As a material for the electrically insulating layer, for example, a resin material or an inorganic material can be utilized. An example of such a resin material is a photosensitive material. Examples of such a photosensitive material are acrylic resin, polyimide resin, siloxane resin, and phenol resin. Examples of such an inorganic material are silicon nitride (SiN), silicon oxynitride (SiON), silicon oxide (SiO), and aluminum oxide (AlO). The electrically insulating layer can be formed solely by a resin material, or by both a resin material and an inorganic material.

### (Anode)

When the organic EL display panel is of the top-emission type, an electrically conductive material having light reflectivity can be utilized as a material for the anode 2. When the organic EL display panel is of the bottom-emission type, an electrically conductive material having light transmissivity can be utilized as a material for the anode 2. Examples of such an electrically conductive material having light reflectivity are aluminum (Al), an alloy of aluminum, silver (Ag), an APC (alloy of silver, palladium, and copper), an ARA (alloy of silver, rubidium, and gold), an MoCr (alloy of molybdenum and chromium), an NiCr (alloy of nickel and chromium), molybdenum (Mo), and an MoW (alloy of molybdenum and tungsten). Examples of such a light-transmissive electrically conductive material are indium tin oxide (ITO) and indium zinc oxide (IZO). The anode 2 may have a multi-layered structure in which a layer of an electrically conductive material having light reflectivity and a layer of a light-transmissive electrically conductive material are stacked.

### (Bank Structure)

As a material for the bank structure 9, for example, an electrically insulating resin material can be utilized. One example of such a resin material is a photosensitive material. Examples of such a photosensitive material are acrylic resin, polyimide resin, siloxane resin, and phenol resin.

### (Hole Injection Layer)

As a material for the hole injection layer 3, a known inorganic material or a known organic material can be utilized. Examples of such a known inorganic material are an oxide of a metal such as silver (Ag), molybdenum (Mo), chromium (Cr), vanadium (V), tungsten (W), nickel (Ni), and iridium (Ir). Examples of such a known organic material are an electrically conductive material such as polyethylenedioxythiophene (PEDOT; mixture of polythiophene and polystyrene sulfonic acid), a low-molecular organic compound such as a triazole derivative, an oxadiazole derivative, an imidazole derivative, a polyarylalkane derivative, a phenylenediamine derivative, an arylamine derivative, an oxazole derivative, a styrylanthracene derivative, a fluorenone derivative, a stilbene derivative, a porphyrin compound, an aromatic tertiary amine compound and a styrylamine compound, or a high-molecular compound such as polyfluorene, a polyfluorene derivative, polyallylamine, and a polyallylamine derivative.

### (Hole Transport Layer)

As a material for the hole transport layer 4, a known organic material can be utilized. Examples of such a known organic material are a triazole derivative, an oxadiazole derivative, an imidazole derivative, a polyarylalkane derivative, a pyrazoline derivative and a pyrazolone derivative, a phenylenediamine derivative, an arylamine derivative, an amino-substituted chalcone derivative, an oxazole derivative, a styrylanthracene derivative, a fluorenone derivative, a hydrazone derivative, a stilbene derivative, a porphyrin compound, an aromatic tertiary amine compound and a styrylamine compound, a butadiene compound, a polystyrene derivative, a hydrazone derivative, a triphenylmethane derivative, and a tetraphenylbenzene derivative.

### (Organic Light-Emitting Layer)

As a material for the organic light-emitting layer 5, a known organic material can be utilized. Examples of such a known organic material are a fluorescent material such as an oxinoid compound, a perylene compound, a coumarin compound, an azacoumarin compound, an oxazole compound, an oxadiazole compound, a perinone compound, a pyrrolo-pyrrole compound, a naphthalene compound, an anthracene compound, a fluorene compound, a fluoranthene compound, a tetracene compound, a pyrene compound, a coronene compound, a quinolone compound, an azaquinolone compound, a pyrazoline derivative and a pyrazolone derivative, a rhodamine compound, a chrysene compound, a phenanthrene compound, a cyclopentadiene compound, a stilbene compound, a diphenylquinone compound, a styryl compound, a butadiene compound, a dicyanomethylene pyran compound, a dicyanomethylene thiopyran compound, a fluorescein compound, a pyrylium compound, a thiapyrylium . compound, a selenapyrylium compound, a telluropyrylium compound, an aromatic aldadiene compound, an oligophenylene compound, a thioxanthene compound, a cyanine compound, an acridine compound, a metal complex of a 8-hydroxyquinoline compound, a metal complex of a 2-bipyridine compound, a complex of a Schiff base and a group III metal, a metal complex of oxine, and rare earth metal complex.

### (Electron Transport Layer)

As a material for the electron transport layer 6, a known organic material or a known inorganic material can be utilized. Examples of such a known organic material are an oxadiazole derivative (OXD), a triazole derivative (TAZ), a phenanthroline derivative (BCP, Bphen), a perinone derivative, a quinolone complex derivative, a silole derivative, a dimesitylboron derivative, and a triarylboron derivative. Examples of such a known inorganic material are an alkali metal and an alkaline earth metal, an oxide of an alkali metal or an alkaline earth metal, and a fluoride of an alkali metal or an alkaline earth metal. Examples of such an alkali metal and an alkaline earth metal are lithium (Li), sodium (Na), cesium (Cs), barium (Ba), and calcium (Ca). Examples of such an oxide of an alkali metal or an alkaline earth metal and a fluoride of an alkali metal or an alkaline earth metal are lithium fluoride (LiF), sodium fluoride (NaF), lithium oxide (LiO), barium oxide (BaO), and cesium carbonate (Cs₂CO₃). In order to improve efficiency in injecting electrons, the above organic material may be doped with an alkali metal or an alkaline earth metal, an oxide of an alkali metal or an alkaline earth metal, or a fluoride of an alkali metal or an alkaline earth metal. Also, the electron transport layer 6 may have a multi-layered structure utilizing the above materials.

### (Cathode)

When the organic EL display panel is of the top-emission type, an electrically conductive material having light transmissivity can be utilized as a material for the cathode 7. When the organic EL display panel is of the bottom-emission type, an electrically conductive material having light reflectivity can be utilized as a material for the cathode 7. Examples of such an electrically conductive material having light reflectivity and such an electrically conductive material having light transmissivity are materials listed as the materials for the anode 2.

### (Sealing Layer)

The sealing layer 8 includes an inorganic material or an resin material. Examples of such an inorganic material are silicon nitride (SiN), silicon oxynitride (SiON), silicon oxide (SiO), and aluminum oxide (AlO). An example of such a resin material is a resin adhesive. The sealing layer 8 may have a multi-layered structure in which a layer including an inorganic material and a layer including a resin material are stacked.

### (Solvent)

When forming the functional layer (for example, the hole injection layer 3, the hole transport layer 4, the organic light-emitting layer 5, and the electron transport layer 6) by the wet process, a solution including a solvent and a functional material for forming a functional layer by the wet process needs to be prepared. As the solvent, a hydrocarbon solvent or an aromatic solvent may be used, such as n-dodecylbenzene, n-decylebenzene, isopropylbiphenyl, 3-ethylbiphenylnonylbenzene, 3-methylbiphenyl, 2-isopropylnaphthalene, 1,2-dimethylnaphthalene, 1,4-dimethylnaphthalene, 1,6-dimethylnaphthalene, 1,3-diphenylpropane, diphenylmetan, octylbenzene, 1,3-dimethylnaphthalene, 1-ethylnaphthalene, 2-ethyl naphthalene, 2,2′-dimethylbiphenyl, 3,3′-dimethylbiphenyl, 2-methylbiphenyl, 1-methylnaphthalene, 2-methylnaphthalene, cyclohexylbenzene, 1,3,5-triisopropylbenzene, hexylbenzene, 1,4-diisopropylbenzene, tetralin, 1,3-diisopropylbenzene, 5-tert-butyl-m-xylene, amylbenzene, 1,2,3,5-tetramethylbenzene, 5-isopropyl-m-xylene, 3,5-dimethylanisole, 4-ethyl-m-xylene, n-butylbenzene, methoxytoluene, sec-butylbenzene, isobutylbenzene, 1,2,4-trimethylbenzene, tert-butylbenzene, 1,3,5-trimethylbenzene, anisole, dibutyl phthalate, dihexyl phthalate, dicyclohexylketone, cyclopentylphenylketone, diethyl phthalate, dimethyl phthalate, hexylbenzoate, isoamylbenzoate, n-buthylbenzoate, 2-cyclohexylcyclohexanone, 2-n-heptylcyclopentanone, phenoxytoluene, diphenylether, 1-ethoxynaphthalene, 2-methoxybiphenyl, isobutylbenzoate, propylbenzoate, isovaleric acid cyclohexyl ester, ethylbenzoate, cyclopropylphenylketone, 2-hexylcyclopentanone, 2-pyrrolidone, 2-cyclopentylcyclopentanone, 1-methyl-2-pyrrolidone, 6-methoxy-1,2,3,4-tetrahydronaphthalene, 2,5-dimethoxytoluene, 1-methoxy-2,3,5-trimethylbenzene, butylphenylether, 3,4-dimethylanisole, methylbenzoate, and 4-ethylcyclohexanone. Alternatively, monohydric alcohol such as methanol, ethanol, isopropyl alcohol, and n-butanol, or a cellosolve solvent such as methylcellosolve and ethylcellosolve may be utilized.

### <4> Manufacturing Method of Organic EL Display Panel

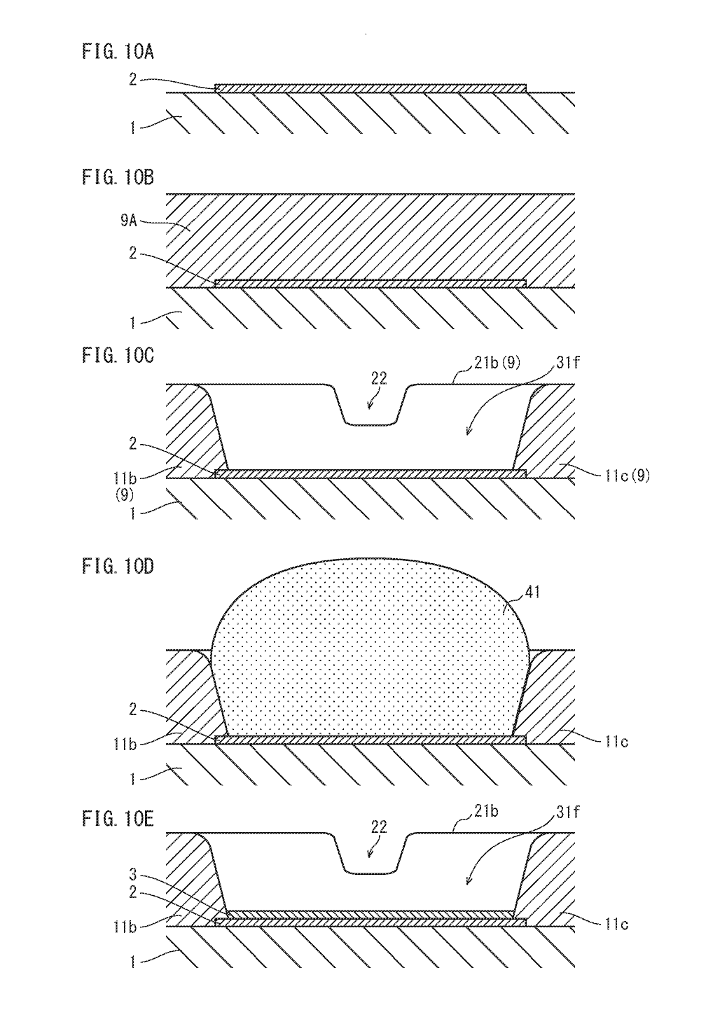

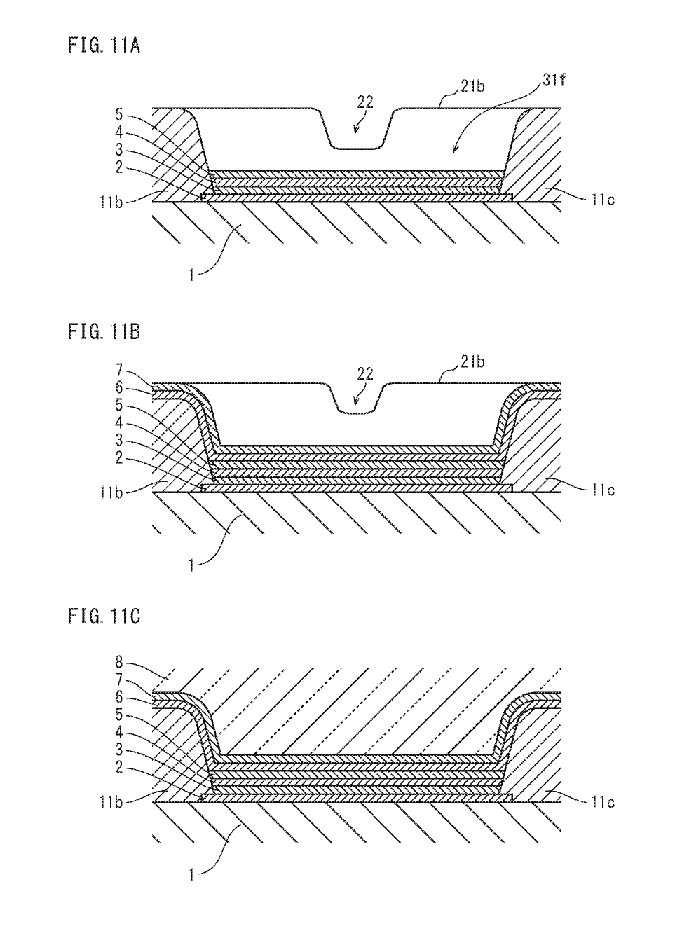

FIGS. 10A, 10B, 10C, 10D, 10E, 11A, 11B, and 11C are partial cross-sectional views illustrating processes for manufacturing the organic EL display panel pertaining to the embodiment of the present invention.

First, the anode 2 is formed on the substrate 1 (FIG. 10A). For example, the material for the anode 2 can be first deposited on the substrate 1 by sputtering or vacuum vapor deposition to form a film. Then, the film can be separated to form the anode 2 by executing etching so that each portion of the film corresponds to one of the subpixels.

Next, on the substrate 1 on which the anode 2 is formed, a film including a material for the bank structure 9 is formed (FIG. 10B). Then, the bank structure 9 is formed by eliminating unnecessary portions of the film (FIG. 10C). For example, when the material for the bank structure 9 is a photosensitive material, the unnecessary portions can be eliminated by applying photolithography. Further, by utilizing a half tone mask in the photolithography, the recesses 31 and the grooves 22 can be foinied in a single manufacturing process.

Next, the solution 41 including a material for the hole injection layer 3 is applied to each of the recesses 31 (FIG. 10D) and dried (FIG. 10E) so as to form the hole injection layer 3. Application and drying of the solution 41 is executed as described above by utilizing FIGS. 5A, 5B, 6A, 6B, and 6C.

In the same manner as the hole injection layer 3, the hole transport layer 4 and the organic light-emitting layer 5 are formed for each of the recesses 31 (FIG. 11A).

Next, the electron transport layer 6 and the cathode 7 are formed (FIG. 11B). The electron transport layer 6 can be formed by, for example, depositing a material for the electron transport layer 6 by utilizing sputtering or vacuum vapor deposition. The cathode 7 is formed in the same manner as the electron transport layer 6.

Next, the sealing layer 8 is formed (FIG. 11C). The sealing layer 8 can be formed by, for example, sputtering, vacuum vapor deposition, chemical vapor deposition (CVD), atomic layer deposition (ALD), and solution application.

### <5> Modification of Shape of Groove

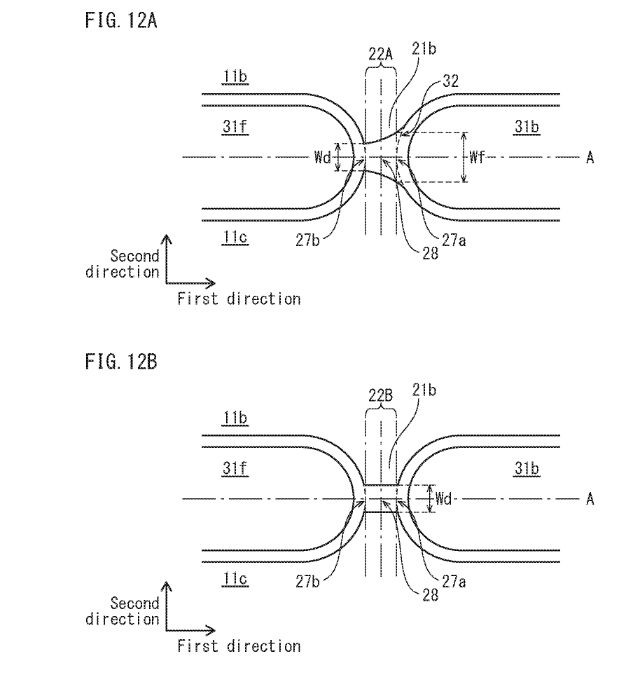

In the embodiment, the shape of the groove 22 is symmetric with respect to the central portion 28, but the present invention should not be construed as being limited to this. For example, as illustrated in the first modification in FIG. 12A, the groove 22 may not have a point-symmetric shape. FIG. 12A illustrates a groove 22A having a width decreasing from the end portion 27a to the end portion 27b. The width of the groove 22A is the smallest at the end portion 27b. In this case as well, the solution can be separated with a high possibility as long as the width Wd of the groove 22A is within the inclusive range from 2 μm to 6 μm.

In the embodiment, the width of the groove 22 changes along the first direction, but the present invention should not be construed as being limited to this.

For example, as illustrated in the second modification in FIG. 12B, a groove 22B may have a width that does not change along the first direction. In this case as well, the solution can be separated with a high possibility as long as the width Wd of the groove 22B is within the inclusive range from 2 μm and to 6 μm.

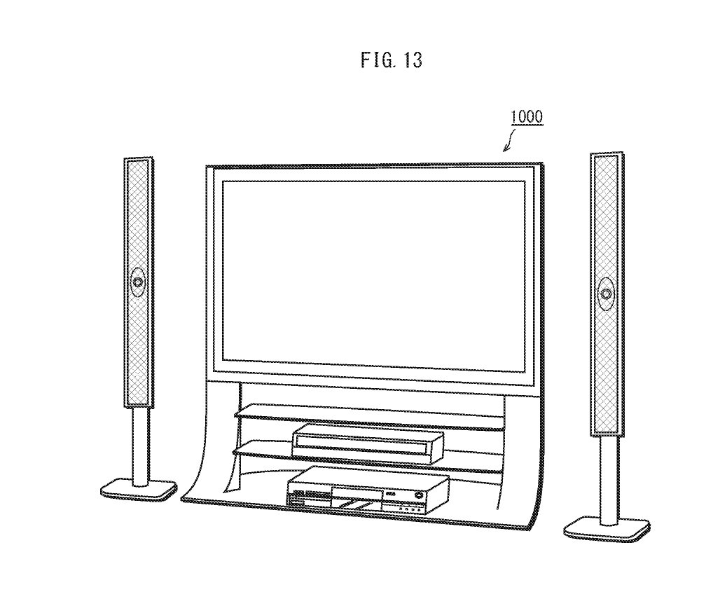

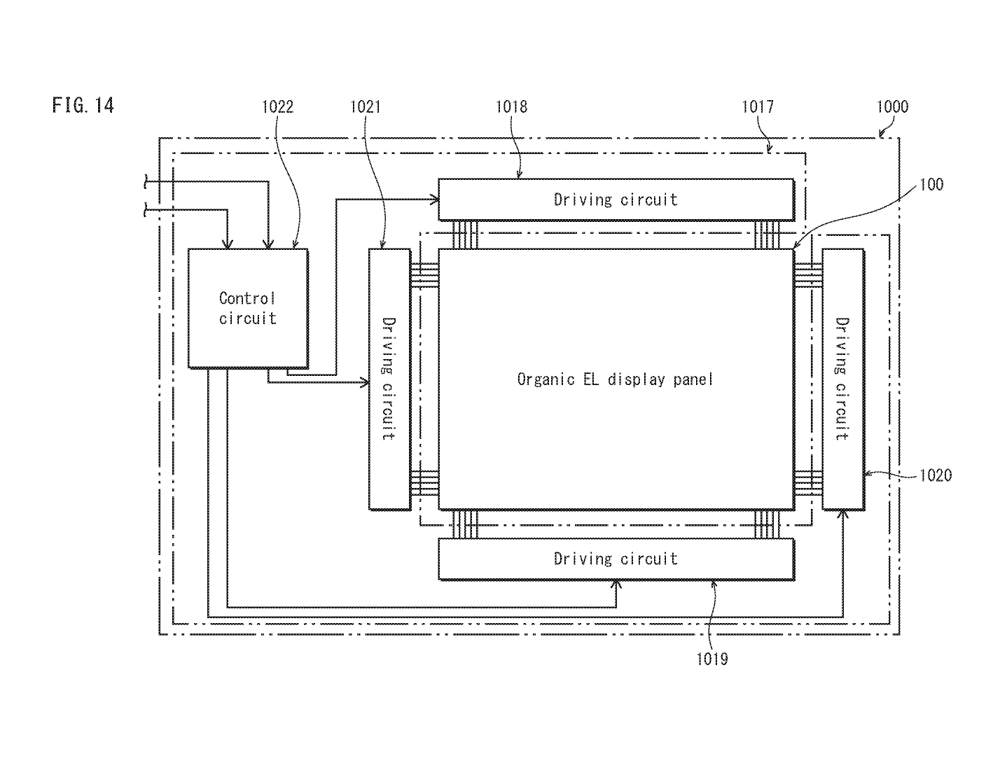

In the embodiment, the upper surfaces 12 of the first banks 11 and the upper surfaces 23 of the second banks 21 are flush with each other, but the present invention should not be construed as being limited to this. For example, the height of the upper surfaces 12 of the first banks 11 and the height of the upper surfaces 23 of the second banks 21 may differ from each other, and consequently, the upper surfaces 12 of the first banks 11 and the upper surfaces 23 of the second banks 12 may have a step difference therebetween.

<6> Display Device The organic EL display panel of the present embodiment can be applied to, for example, a display device 1000 as illustrated in FIG. 13. As illustrated in FIG. 14, the display device 1000 includes an organic EL display panel 100 and a driving control circuit 1017. The organic EL display panel 100 is the organic EL display panel described in the embodiment. The driving control circuit 1017 includes driving circuits 1018, 1019, 1020, 1021, and a control circuit 1022. The control circuit 1022 receives video signals from the outside, and converts the video signals into voltage signals that are suitable for the TFT driving circuits in the organic EL display panel 100. The driving circuits 1018, 1019, 1020, and 1021 transmit the voltage signals received from the control circuit 1022 to the TFT driving circuits in the organic EL display panel 100.

In the above embodiment, the hole injection layer 3, the hole transport layer 4, and the organic light-emitting layer 5 are formed by the wet process, but the present invention should not be construed as being limited to this. Forming at least one of such functional layers by the wet process is sufficient.

In the above embodiment, each of the organic EL elements has a layered structure including the anode 2, the hole injection layer 3, the hole transport layer 4, the organic light-emitting layer 5, the electron transport layer 6, and the cathode 7, but the present invention should not be construed as being limited to this. The layers between the anode 2 and the organic light-emitting layer 5 (the hole injection layer 3, the hole transport layer 4) may or may not be disposed, as necessary. Similarly, the layers between the organic light-emitting layer 5 and the cathode 7 (the electron transport layer 6) may or may not be disposed, as necessary.

In the above embodiment, the anode 2 is fonned on the substrate 1, but the present invention should not be construed as being limited to this. The present invention may be realized in a so-called inverted structure. An inverted structure is a structure in which the cathode 7 is formed on the substrate 1, and the electron transport layer 6, the organic light-emitting layer 5, the hole transport layer 4, the hole injection layer 3, and the anode 2 are stacked on the cathode 7 in this order.

### INDUSTRIAL APPLICABILITY

The present invention can be applied to, for example, display devices.

### REFERENCE SIGNS LIST

1 substrate

2 anode

3 hole injection layer

4 hole transport layer

5 organic light-emitting layer

6 electron transport layer

7 cathode

8 sealing layer

9 bank structure

10 organic EL display panel

11, 11a-11d first bank

12 upper surface of first bank

21, 21a -21h second bank

22 groove

23 upper surface of second bank

27a, 27b end portion of groove

28 central portion of groove

31, 31a-31l recess

32 outline of recess

41 solution

1. An organic electroluminescence (EL) display panel, comprising:
a pair of first banks, each of the first banks having a greater length in a first direction than in a second direction orthogonal to the first direction, the pair of first banks disposed with a gap therebetween along the second direction;
a plurality of second banks each spanning the gap between the first banks, the second banks disposed at intervals along the first direction; and
a plurality of functional layers disposed within respective ones of a plurality of recesses defined by the first banks and the second banks, each of the functional layers corresponding to at least a portion of an organic EL element, wherein
each of the second banks has a groove at an upper surface thereof, the groove connecting adjacent recesses, and having a width, along the second direction, smaller than a width of the adjacent recesses along the second direction and within an inclusive range from 2 μm to 6 μm, the adjacent recesses being ones of the plurality of recesses that. are adjacent to each other with the second bank therebetween.

2. The organic EL display panel of claim 1, wherein
for each of the second banks, the width of the groove along the second direction is equal to or smaller than one fourth of the width of the adjacent recesses along the second direction.

3. The organic EL display panel of claim 2, wherein
upper surfaces of the first banks are flush with upper surfaces of the second banks, and
for each of the second banks, the groove has a depth equal to or greater than 30% of a height of the first banks.

4. The organic EL display panel of claim 3, wherein
the second banks include an electrically insulating material, and
for each of the second banks, the depth of the groove is equal to or less than a value calculated by subtracting 300 nm from the height of the first banks.

5. The organic EL display panel of claim 1, wherein
each of the second banks separates one of the functional layers in one of the adjacent recesses from another of the functional layers in the other of the adjacent recesses.

6. The organic EL display panel of claim 1, wherein
the functional layers include an organic material.

7. The organic EL display panel of claim 1, wherein
the groove has different widths along the second direction at different positions thereof along the first direction, and the width within the inclusive range from 2 μm to 6 μm is a width at a position where the groove has a minimum width along the second direction.

8. The organic EL display panel of claim 7, wherein
the groove includes:
two end portions each connecting with one of the adjacent recesses; and
a central portion between the two end portions, and
the width of the groove along the second direction gradually decreases from the two end portions of the groove to the central portion of the groove.

9. A manufacturing method of an organic EL display panel, comprising:
forming a pair of first banks, each of the first banks having a greater length in a first direction than in a second direction orthogonal to the first direction, the pair of first banks disposed with a gap therebetween along the second direction;
forming a plurality of second banks each spanning the gap between the first banks and disposed at intervals along the first direction; and
forming a plurality of functional layers disposed within respective ones of a plurality of recesses defined by the first banks and the second banks, each of the functional layers corresponding to at least a portion of an organic EL element, wherein
each of the second banks has a groove at an upper surface thereof, the groove connecting adjacent recesses, and having a width, along the second direction, smaller than a width of the adjacent recesses along the second direction and within an inclusive range from 2 μm to 6 μm, the adjacent recesses being ones of the plurality of recesses that are adjacent to each other with the second bank therebetween, and
the functional layers are formed by applying a solution including a functional material and drying the applied solution, the applied solution including portions positioned in the recesses and portions positioned in the grooves of the second banks.

10. The manufacturing method of the organic EL display panel of claim 9, wherein
the portions positioned in the recesses are connected by the portions positioned in the grooves, and
the drying of the applied solution separates the functional layers to be within respective ones of the recesses.
